(19) United States
(12) Patent Application Publication
(10) Pub. No.: US 2016/0013383 A1
(43) Pub. Date: Jan. 14, 2016

(54) LIGHT-EMITTING DEVICE

(71) Applicant: EPISTAR CORPORATION, Hsinchu (TW)

(72) Inventors: Chien-Ming WU, Hsinchu (TW); Rong-Ren LEE, Hsinchu (TW); Tzu-Chieh HSU, Hsinchu (TW); Ming-Nam CHANG, Hsinchu (TW)

(21) Appl. No.: 14/796,654

(22) Filed: Jul. 10, 2015

(30) Foreign Application Priority Data
Jul. 14, 2014 (TW) 103124203

(51) Int. Cl. H01L 33/60; H01L 33/30

(52) U.S. Cl. CPC H01L 33/60; H01L 33/30

(57) ABSTRACT

A light-emitting device comprising a substrate; a semiconductor stack capable of emitting a light; a first reflecting structure between the substrate and the semiconductor stack to reflect the light; and a second reflecting structure between the substrate and the semiconductor stack, wherein the first reflecting structure has a maximum reflectivity when the light is incident to the first reflecting structure at a first incident angle, the second reflecting structure has a maximum reflectivity when the light is incident to the second reflecting structure at a second incident angle.

### REFERENCE TO RELATED APPLICATION

This present application claims the right of priority based on TW application Serial No. 103124203, filed on Jul. 14, 2014, and the content of which is hereby incorporated by reference in its entirety.

### TECHNICAL FIELD

The disclosure relates to a light-emitting device, and more particularly, to a light-emitting device comprising a reflecting structure to reflect a light, wherein the reflecting structure has a maximum reflectivity when the light is incident to the reflecting structure at an incident angle.

### DESCRIPTION OF BACKGROUND ART

Light-emitting diode (LED) is a solid-state semiconductor light-emitting device. The advantages of the light-emitting diode are low power consumption, low heat generation, long working life, shock resistant, small volume, fast response, and excellent optoelectronic characteristics, such as stable emission wavelength. The light-emitting diodes are widely used in household appliances, equipment indicating lights, and optoelectronic products.

### SUMMARY OF THE DISCLOSURE

The disclosure is to provide a light-emitting device comprising a substrate; a semiconductor stack capable of emitting a light; a first reflecting structure formed between the substrate and the semiconductor stack to reflect the light; and a second reflecting structure formed between the substrate and the semiconductor stack, wherein the first reflecting structure has a maximum reflectivity when the light is incident to the first reflecting structure at a first incident angle, the second reflecting structure has a maximum reflectivity when the light is incident to the second reflecting structure at a second incident angle.

Embodiments of the present disclosure will now be described referring to the drawings.

### BRIEF DESCRIPTION OF THE DRAWINGS

FIG. 1 shows a cross-sectional view of a light-emitting device in accordance with an embodiment of the present disclosure;

FIG. 2 shows a cross-sectional view of part of the light-emitting device in accordance with an embodiment of the present disclosure;

FIG. 3 shows a cross-sectional view of a light-emitting device in accordance with an embodiment of the present disclosure; and

FIG. 4 shows a cross-sectional view of part of the light-emitting device in accordance with an embodiment of the present disclosure.

### DETAILED DESCRIPTION OF THE PRESENT DISCLOSURE

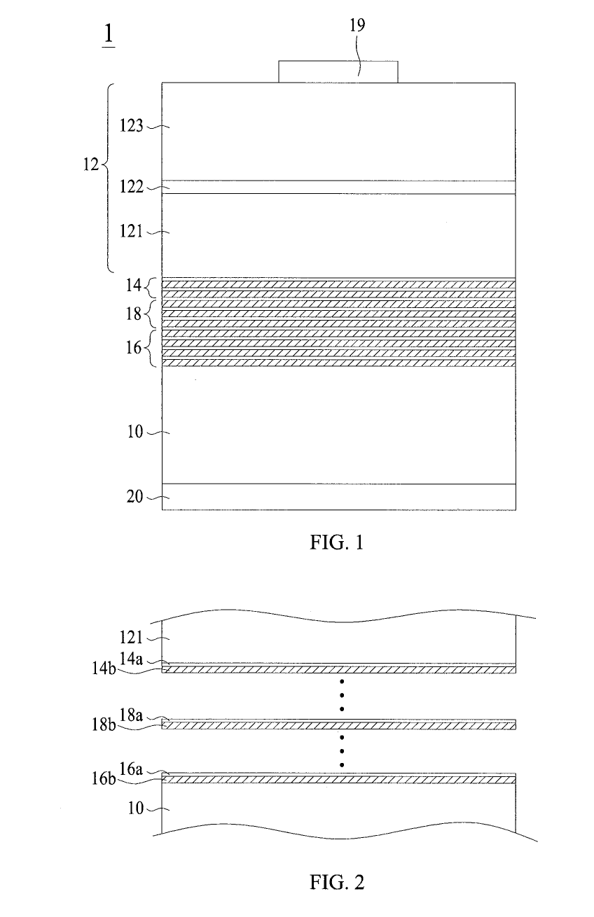

FIG. 1 shows a cross-sectional view of a light-emitting device 1 in accordance with an embodiment of the present disclosure. Light-emitting device 1, such as light-emitting diode, comprises a substrate 10; and a semiconductor stack 12 capable of emitting a light formed on the substrate 10. One or a plurality of reflecting structures, such as a first reflecting structure 14, a second reflecting structure 16, and a third reflecting structure 18, formed between the substrate 10 and the semiconductor stack 12 to reflect the light emitted from the semiconductor stack 12, wherein the plurality of reflecting structures reflects lights having substantially same wavelength. The first reflecting structure 14 has a maximum reflectivity when the light emitted from the semiconductor stack 12 is incident to the first reflecting structure 14 at a first incident angle θ₁, the second reflecting structure 16 has a maximum reflectivity when the light emitted from the semiconductor stack 12 is incident to the second reflecting structure 16 at a second incident angle θ₂, and the second incident angle θ₂ is different from the first incident angle θ₁. For example, the first reflecting structure 14 has a maximum reflectivity when the light emitted from the semiconductor stack 12 is incident to the first reflecting structure 14 at the first incident angle θ₁ ranging between 0 and 20 degrees, wherein the maximum reflectivity is larger than 50%, preferably larger than 80%, more preferably larger than 90%, while the range of the first incident angle θ₁ is not limited thereto. The second reflecting structure 16 has a maximum reflectivity when the light emitted from the semiconductor stack 12 is incident to the second reflecting structure 16 at the second incident angle θ₂ ranging between 20 and 60 degrees, wherein the maximum reflectivity is larger than 50%, preferably larger than 80%, more preferably larger than 90%, while the range of the second incident angle θ₂ is not limited thereto. In an embodiment of the present disclosure, the first incident angle θ₁ or the second incident angle θ₂ can be a certain number or a range.

In an embodiment of the present disclosure, the substrate 10 can be a supporting carrier to support the semiconductor stack 12. The semiconductor stack 12 can be formed on a temporary substrate (not shown) first, and then bonded to the substrate 10 through the reflecting structure described above, wherein the temporary substrate can be removed or retained based on the consideration of light extraction efficiency of the light-emitting device 1. In an embodiment of the present disclosure, the substrate 10 can be a growth substrate comprising GaAs wafer for the growth of aluminum gallium indium phosphide (AlGaInP), sapphire (Al₂O₃) wafer, gallium nitride (GaN) wafer or silicon carbide (SiC) wafer for the growth of indium gallium nitride (InGaN). The semiconductor stack 12 comprising optoelectronic characteristics, such as a light-emitting stack, can be formed on the substrate 10 by metallic-organic chemical vapor deposition (MOCVD), molecular beam epitaxy (MBE), hydride vapor phase epitaxy (HYPE), sputtering, or ion plating.

The semiconductor stack 12 comprises a first conductive type semiconductor layer 121, a second conductive type semiconductor layer 123, and an active layer 122 between the first conductive type semiconductor layer 121 and the second conductive type semiconductor layer 123. The first conductive type semiconductor layer 121 and the second conductive type semiconductor layer 123 can be cladding layer or confinement layer that respectively provides electrons and holes to recombine in the active layer 122 to emit a light under an electrical current driving. The material of the semiconductor stack 12 comprises group III-V semiconductor material, such as AlₓIn_{y}Ga_{(1-x-y)}N or AlₓIn_{y}Ga_{(1-x-y)}P, wherein 0≦x, y≦1;(x+y)≦1. In accordance with the material of the active layer 122, the semiconductor stack 12 can emit red light having wavelength between 610 nm and 650 nm, green light having wavelength between 530 nm and 570 nm, or blue light having wavelength between 450 nm and 490 nm. In an embodiment of the present disclosure, the substrate 10 and the semiconductor stack 12 can be a single crystalline epitaxy structure. After forming the semiconductor stack 12, electrodes, such as a first electrode 20 and a second electrode 19, are formed by sputtering process and to be electrically connected to the semiconductor stack 12 under an electrical current driving.

In an embodiment of the present disclosure, the reflecting structure, such as the first reflecting structure 14, the second reflecting structure 16, or the third reflecting structure 18, comprises dielectric material, such as SiOₓ, SiN_{y}, MgF₂, Nb₂O₅, or Ta₂O₅, or semiconductor material, such as group III-V semiconductor material, such as AlₓGa₍₁₋ₓ₎As, wherein 0≦x≦1. The reflecting structure can be formed between the substrate 10 and the semiconductor stack 12 by metallic-organic chemical vapor deposition (MOCVD), molecular beam epitaxy (MBE), hydride vapor phase epitaxy (HYPE), sputtering, or ion plating. In an embodiment of the present disclosure, the reflecting structure can be a single crystalline epitaxy structure. The first reflecting structure 14 and/or the second reflecting structure 16 can be doped or undoped. Specifically, when the first reflecting structure 14 and/or the second reflecting structure 16 constitute a part of an electrical conduction path of the light-emitting device 1, the first reflecting structure 14 and/or the second reflecting structure 16 can be doped. When the first reflecting structure 14 and/or the second reflecting structure 16 do not constitute a part of an electrical conduction path of the light-emitting device 1, the first reflecting structure 14 and/or the second reflecting structure 16 can be undoped. For example, as shown in FIG. 1, the first electrode 20 and the second electrode 19 are formed on opposite sides of the substrate 10, and the first reflecting structure 14 and the second reflecting structure 16 comprise a dopant, such as an n-type dopant or a p-type dopant. In another embodiment of the present disclosure, the first electrode 20 and the second electrode 19 are formed on the same side of the substrate 10 (not shown), and the first reflecting structure 14 and the second reflecting structure 16 can be doped or undoped.

FIG. 2 shows a cross-sectional view of part of the light-emitting device 1 in accordance with an embodiment of the present disclosure. As shown in FIG. 2, the first reflecting structure 14 and the second reflecting structure 16 can be distributed bragg reflectors (DBR). The first reflecting structure 14 and the second reflecting structure 16 comprise a high refractive index layer and a low refractive index layer stacked alternately to form one or more pairs of a stack structure. The first reflecting structure 14 and the second reflecting structure 16 comprise same or different materials. Furthermore, when the first reflecting structure 14 and the second reflecting structure 16 comprise same materials, the first reflecting structure 14 and the second reflecting structure 16 comprise same or different material composition. In the embodiment, the first reflecting structure 14 comprises a first stack comprising a pair provided with a first layer 14a having a first refractive index and a second layer 14b having a second refractive index, wherein the first refractive index is different from the second refractive index. The reflectivity of the first reflecting structure 14 can be adjusted by adjusting the difference between the first refractive index and the second refractive index. Specifically, the reflectivity of the first reflecting structure 14 is increased by increasing the difference between the first refractive index and the second refractive index. On the contrary, the reflectivity of the first reflecting structure 14 is decreased by decreasing the difference between the first refractive index and the second refractive index. In an embodiment of the present disclosure, the difference between the first refractive index and the second refractive index is between 0.4 and 1. For example, the first reflecting structure 14 comprises the first layer 14a, such as Alₓ₁Ga₍₁₋ₓ₁₎As, and the second layer 14b, such as Al_{y1}Ga_{(1-y1)}As, which are alternately stacked to form one or more pairs of a stack structure, wherein x1≠y1. Accompany with increasing x1 or y1 value of Alₓ₁Ga₍₁₋ₓ₁₎As or Al_{y1}Ga_{(1-y1)}As, in other words, increasing Al composition, the refractive index of Alₓ₁Ga₍₁₋ₓ₁₎As or Al_{y1}Ga_{(1-y1)}As is decreased. On the contrary, decreasing Al composition can increase the refractive index of Alₓ₁Ga₍₁₋ₓ₁₎As or Al_{y1}Ga_{(1-y1)}As. The second reflecting structure 16 comprises a second stack comprising a pair provided with a third layer 16a having a third refractive index and a fourth layer 16b having a fourth refractive index, wherein the third refractive index is different from the fourth refractive index. The reflectivity of the second reflecting structure 16 can be adjusted by adjusting the difference between the third refractive index and the fourth refractive index. Specifically, the reflectivity of the second reflecting structure 16 is increased by increasing the difference between the third refractive index and the fourth refractive index. On the contrary, the reflectivity of the second reflecting structure 16 is decreased by decreasing the difference between the third refractive index and the fourth refractive index. In an embodiment of the present disclosure, the difference between the third refractive index and the fourth refractive index is between 0.4 and 1. For example, the second reflecting structure 16 comprises the third layer 16a, such as Alₓ₂Ga₍₁₋ₓ₂₎As, and the fourth layer 16b, such as Al_{y2}Ga_{(1-y2)}As, which are alternately stacked to form one or more pairs of a stack structure, wherein x2≠y2. Accompany with increasing x2 or y2 value of Alₓ₂Ga₍₁₋ₓ₂₎As or Al_{y2}Ga_{(1-y2)}As, in other words, increasing Al composition, the refractive index of Alₓ₂Ga₍₁₋ₓ₂₎As or Al_{y2}Ga_{(1-y2)}As is decreased. On the contrary, decreasing Al composition can increase the refractive index of Alₓ₂Ga₍₁₋ₓ₂₎As or Al_{y2}Ga_{(1-y2)}AS.

The light-emitting device 1, such as a light-emitting diode, is required to adjust optical field distribution for different applications. The optical field distribution can be defined by a far field angle; the smaller the far field angle is, the higher the directivity of the light-emitting diode is. On the contrary, the larger the far field angle is, the lower the directivity of the light-emitting diode is. In an embodiment of the present disclosure, the optical field distribution of the light-emitting device 1 is adjusted by the first reflecting structure 14 and the second reflecting structure 16, which have different reflectivity at different angles for the light emitted from the semiconductor stack 12. For example, an optical field distribution having a larger far field angle can be provided by adjusting structures of the first reflecting structure 14 and the second reflecting structure 16 to provide lower reflectivity for a smaller incident angle and higher reflectivity for a larger incident angle. The first reflecting structure 14 has lower reflectivity when the light emitted from the semiconductor stack 12 is incident to the first reflecting structure 14 at the first incident angle θ₁ ranging between 0 and 20 degrees, and the second reflecting structure 16 has higher reflectivity when the light emitted from the semiconductor stack 12 is incident to the second reflecting structure 16 at the second incident angle θ₂ ranging between 20 and 60 degrees. In another embodiment, the first reflecting structure 14 comprises a first stack having a first pair, the second reflecting structure 16 comprises a second stack having a second pair, and a number of the first pair constituting the first stack of the first reflecting structure 14 is different from a number of the second pair constituting the second stack of the second reflecting structure 16. For example, the optical field distribution of the light-emitting device 1 is adjusted by decreasing the number of the first pair constituting the first stack of the first reflecting structure 14 and/or increasing the number of the second pair constituting the second stack of the second reflecting structure 16.

In an embodiment of the present disclosure, the first reflecting structure 14 comprises the first stack comprising a pair provided with a first thickness different from a second thickness of a pair of the second stack of the second reflecting structure 16. The first reflecting structure 14 and the second reflecting structure 16 respectively have maximum reflectivity when the light emitted from the semiconductor stack 12 is incident thereon at different incident angles θ, and the thickness of the pair of the reflecting structure is increased corresponding to an increase of the incident angle. Furthermore, a thickness of any layer of the first reflecting structure 14 and the second reflecting structure 16, such as the first layer 14a, the second layer 14b, the third layer 16a, or the fourth layer 16b is approximately multiple of one-quarter of the wavelength of the light emitted from the semiconductor stack 12, and is inversely proportional to cos θ. Specifically, the first layer 14a and the second layer 14b constituting the first reflecting structure 14, or the third layer 16a and the fourth layer 16b constituting the second reflecting structure 16 respectively has a thickness d. When the active layer 122 emits a light having a wavelength λ, any layer of the reflecting structure has refractive index n, the thickness d satisfies the formula d=(λ/(4n))/cos θ.

In an embodiment of the present disclosure, in order to increase the light extraction efficiency and the light extraction angle, the light-emitting device 1 optionally comprises a third reflecting structure 18 formed between the first reflecting structure 14 and the second reflecting structure 16, wherein the third reflecting structure 18 has a maximum reflectivity when the light emitted from the semiconductor stack 12 is incident to the third reflecting structure 18 at a third incident angle θ₃, wherein the maximum reflectivity is larger than 50%, preferably larger than 80%, more preferably larger than 90%. The third incident angle θ₃ can be between the first incident angle θ₁ and the second incident angle θ₂, or the third incident angle θ₃ can be larger than the first incident angle θ₁ and/or the second incident angle θ₂, or the third incident angle θ₃ can be smaller than the first incident angle θ₁ and/or the second incident angle θ₂. The third reflecting structure 18 comprises a third stack comprising a pair provided with a fifth layer 18a having a fifth refractive index and a sixth layer 18b having a sixth refractive index. When the third incident angle θ₃ is between the first incident angle θ₁ and the second incident angle θ₂, a third thickness of a pair of the third stack of the third reflecting structure 18 is adjusted in accordance with a variation of the third incident angle θ₃. The third thickness of the pair of the third stack of the third reflecting structure 18 is between the first thickness of the pair of the first stack of the first reflecting structure 14 and the second thickness of the pair of the second stack of the second reflecting structure 16. The fifth layer 18a and the sixth layer 18b constituting the third reflecting structure 18 respectively has a thickness d. When the active layer 122 emits a light having a wavelength λ, any layer of the third reflecting structure 18 has refractive index n, the thickness d satisfies the formula d=(λ/(4n))/cos θ.

Taking the semiconductor stack 12 capable of emitting red light having a wavelength λ at 630 nm as an example, the light emitted from the semiconductor stack 12 is toward multiple directions, in order to improve the light extraction efficiency of the light from the light extraction surface of the light-emitting device 1, one or a plurality of reflecting structures, such as the first reflecting structure 14 and the second reflecting structure 16, can be formed between the substrate 10 and the semiconductor stack 12 to reflect the light emitted toward the substrate 10. In an embodiment of the present disclosure, the first reflecting structure 14 is provided with a first stack having one or more first pairs, and the first pair is provided with the first layer 14a having higher refractive index and the second layer 14b having lower refractive index alternately stacked. The thickness d₁ of the first layer 14a or the second layer 14b satisfies the formula d₁=(λ/(4n₁))/cos θ₁, wherein n₁ is the refractive index of the first layer 14a or the second layer 14b, θ₁ is the incident angle at which the light from the semiconductor stack 12 being incident to the first reflecting structure 14. For example, the first reflecting structure 14 is configured to form a structure having one or more pairs with AlAs/Al_{0.6}Ga_{0.4}As to provide the first stack for reflecting a wavelength at 630 nm. When the light from the semiconductor stack 12 is incident to the first reflecting structure 14 at the first incident angle θ₁ between 0 and 20 degrees, the first reflecting structure 14 has a higher reflectivity for the light having wavelength at 630 nm at the first incident angle θ₁, and a lower reflectivity for the light having wavelength at 630 nm out of the first incident angle θ₁. Part of the light emitted from the semiconductor stack 12, which has wavelength at 630 nm, is incident to the first reflecting structure at an angle out of the range of the first incident angle θ₁ and not reflected by the first reflecting structure. The part of the light penetrates the first reflecting structure 14 and is incident to the second reflecting structure 16 at the second incident angle θ₂ different the first incident angle θ₁. In an embodiment of the present disclosure, the second reflecting structure 16 is provided with a second stack having one or more second pairs, and the second pair is provided with the third layer 16a having higher refractive index and the fourth layer 16b having lower refractive index alternately stacked. The thickness d₂ of the third layer 16a or the fourth layer 16b satisfies the formula d₂=(λ/(4n₂))/cos θ₂, wherein n₂ is the refractive index of the third layer 16a or the fourth layer 16b, θ₂ is the incident angle that the light from the semiconductor stack 12 incident to the second reflecting structure 16. For example, the second reflecting structure 16 is configured to form a structure having one or more pairs of the second stack with AlAs/Al_{0.6}Ga_{0.4}As for reflecting a wavelength at 630 nm. When the light from the semiconductor stack 12 is incident to the second reflecting structure 16 at the second incident angle θ₂ between 20 and 29 degrees, the second reflecting structure 16 has a higher reflectivity for the light having wavelength at 630 nm between 20 and 29 degrees, and a lower reflectivity for the light having wavelength at 630 nm out of 20 and 29 degrees. In order to improve the light extraction efficiency of the light-emitting device 1, a further reflectivity optimization is provided by increasing a number of the reflecting structures for the incident light at different incident angles.

In an embodiment of the present disclosure, when the refractive index difference between the high refractive index layer and the low refractive index layer is between 0.4 and 1, preferably, six to thirteen reflecting structures are formed between the substrate 10 and the semiconductor stack 12 to respectively reflect the light incident between 0˜90 degrees for reflectivity optimization. In order to provide the six to thirteen reflecting structures having a maximum reflectivity for the light incident thereon at different incident angles, the thickness of one pair of the stack constituting the reflecting structure is thicker as the incident angle is larger. In accordance with an embodiment of the present disclosure, the table shown below provides thirteen reflecting structures to reflect the light having wavelength at 630 nm with the incident angle of between 0˜60 degrees. The thirteen reflecting structures respectively has the maximum reflectivity to the light having wavelength at 630 nm at different incident angles, and respectively comprises the stack having one pair composed of AlAs/Al_{0.6}Ga_{0.4}As. One pair of the stack of one reflecting structure has a thickness different from one pair of the stack of another reflecting structure, and the thickness of the pair of the stack composing the reflecting structure is increased as the incident angle is enlarged. Taking the stack comprising one pair of AlAs/Al_{0.6}Ga_{0.4}As for an example, the first reflecting structure comprises the first stack comprising the pair of AlAs/Al_{0.6}Ga_{0.4}As, the thickness of the pair of the first stack is approximately 99 nm, and the first reflecting structure has a maximum reflectivity for the light having wavelength at 630 nm between 0˜20 degrees of the incident angle. The second reflecting structure comprises the second stack comprising the pair of AlAs/Al_{0.6}Ga_{0.4}As, the thickness of the pair of the second stack is approximately 106.6 nm, and the second reflecting structure has a maximum reflectivity to the light having wavelength at 630 nm between 20˜29 degrees of the incident angle.

| | AlAs/Al_{0.6}Ga_{0.4}As | incident |
|---|---|---|
| | thickness (nm) | angle |
| 1ₛₜ reflecting structure | 99.0 | 0~20 |
| 2_{nd} reflecting structure | 106.6 | 20~29 |
| 3_{rd} reflecting structure | 115.8 | 29~35 |
| 4ₜₕ reflecting structure | 123.4 | 35~39 |
| 5ₜₕ reflecting structure | 131.0 | 39~42 |
| 6ₜₕ reflecting structure | 138.6 | 42~45 |
| 7ₜₕ reflecting structure | 147.8 | 45~48 |
| 8ₜₕ reflecting structure | 158.4 | 48~51 |
| 9ₜₕ reflecting structure | 170.6 | 51~53 |
| 10ₜₕ reflecting structure | 182.8 | 53~55 |
| 11ₜₕ reflecting structure | 198.0 | 55~57 |
| 12ₜₕ reflecting structure | 213.3 | 57~59 |
| 13ₜₕ reflecting structure | 228.5 | 59~60 |

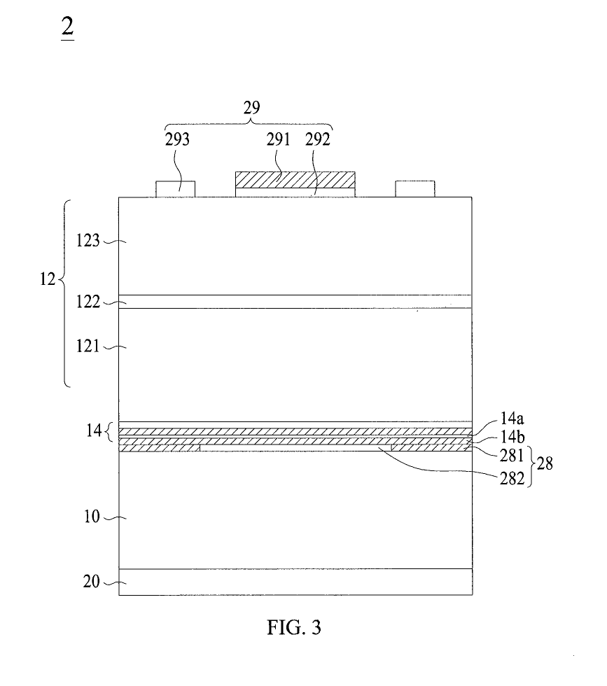

FIG. 3 shows a cross-sectional view of a light-emitting device 2 in accordance with an embodiment of the present disclosure. As shown in FIG. 3, the second reflecting structure 28 is between the substrate 10 and the first reflecting structure 14. Besides the second reflecting structure 28 of the light-emitting device 2 is different from the reflecting structure of the light-emitting device 1, the other structure of the light-emitting device 2 is approximately same as that of the light-emitting device 1. The elements of the light-emitting device 2 denoted by same numbers of the light-emitting device 1 are not addressed again.

In an embodiment of the present disclosure, the material of the second reflecting structure 28 comprises dielectric material, such as SiO₂, Si₃N₄, MgF₂, Nb₂O₅ or Ta₂O₅, or semiconductor material, such as AlₓGa₍₁₋ₓ₎As, wherein 0≦x≦1. The second reflecting structure 28 can be formed between the substrate 10 and the semiconductor stack 12 by metallic-organic chemical vapor deposition (MOCVD), molecular beam epitaxy (MBE), hydride vapor phase epitaxy (HYPE), sputtering, or ion plating.

The second reflecting structure 28 can be doped or undoped. Specifically, when the second reflecting structure 28 constitutes a part of an electrical conduction path of the light-emitting device 2, the second reflecting structure 28 can be doped. When the second reflecting structure 28 does not constitute a part of an electrical conduction path of the light-emitting device 2, the second reflecting structure 28 can be undoped. For example, as shown in FIG. 3, the first electrode 20 and the second electrode 29 are formed on opposite sides of the substrate 10, and the second reflecting structure 28 comprise a dopant, such as an n-type dopant or a p-type dopant. In another embodiment of the present disclosure, the first electrode 20 and the second electrode 29 are formed on the same side of the substrate 10 (not shown), and the second reflecting structure 28 can be doped or undoped. In a variant of the embodiment, the second reflecting structure 28 can be a single layer structure comprising dielectric material having low refractive index, such as SiO₂, Si₃N₄, MgF₂, Nb₂O₅ or Ta₂O₅, or semiconductor material, such as AlₓGa₍₁₋ₓ₎As, wherein the material of the sidewall of the second reflecting structure 28, such as AlₓGa₍₁₋ₓ₎As, can be oxidized in an environment by wet oxidation process. When the first electrode 20 and the second electrode 29 are formed on the same side of the substrate 10 (not shown), AlₓGa₍₁₋ₓ₎As of the second reflecting structure 28 can be totally oxidized to form aluminum oxide; when the first electrode 20 and the second electrode 29 are formed on opposite sides of the substrate 10 as shown in FIG. 3, AlₓGa₍₁₋ₓ₎As of the second reflecting structure 28 is partially oxidized to form an oxidized region 281 and a un-oxidized region 282 surrounded by the oxidized region 281, wherein the oxidized region 281 comprises aluminum oxide, the un-oxidized region 282 comprises AlₓGa₍₁₋ₓ₎As, 0≦x≦0.8, and the un-oxidized region 282 constitutes a part of an electrical conduction path of the light-emitting device 2.

The light emitted from the semiconductor stack 12 is toward multiple directions, wherein part of the light emitted towards the substrate 10 is incident to the first reflecting structure 14 at the first incident angle θ₁. The light incident at an incident angle smaller than the first incident angle θ₁ is reflected by the first reflecting structure 14, and the light incident at an incident angle larger than the first incident angle θ₁ is reflected by the second reflecting structure 28. Furthermore, the second reflecting structure 28 comprises lower refractive index compared with that of adjacent layers, such as the semiconductor stack 12 or the first reflecting structure 14. When the light emitted from a layer having higher refractive index enters the adjacent second reflecting structure 28 having lower refractive index at the second incident angle θ₂ which is larger than the critical angle, the light is reflected back to the layer having higher refractive index.

In a variant of the embodiment, as shown in FIG. 3, the first reflecting structure 14 is formed between the semiconductor stack 12 and the second reflecting structure 28. The second layer 14b of the first reflecting structure 14 comprises a refractive index n, the second layer 14b is adjacent to a layer of the second reflecting structure 28, and a refractive index difference of the two adjacent layers is Δ n, wherein 1-sin θ₂<Δn/n<1-sin θ₁.

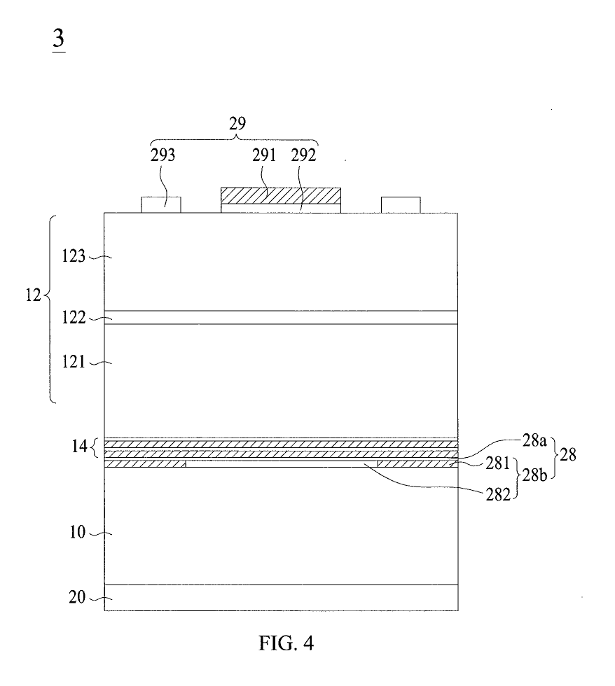

FIG. 4 shows a cross-sectional view of the light-emitting device 3 in accordance with a variant of the embodiment of the present disclosure. In the variant of the embodiment, the second reflecting structure 28 can be a multi-layer structure. As shown in FIG. 4, the second reflecting structure 28 can be a distributed bragg reflector (DBR) and comprises a high refractive index layer and a low refractive index layer. The high refractive index layer and the low refractive index layer are alternately stacked to form one or more pairs of the stack. In the embodiment, the second reflecting structure 28 comprises a second stack comprising a pair provided with a third layer 28a having a third refractive index and a fourth layer 28b having a fourth refractive index, wherein the third refractive index is different from the fourth refractive index. The reflectivity of the second reflecting structure 28 can be adjusted by adjusting a difference between the third refractive index and the fourth refractive index. Specifically, the reflectivity of the second reflecting structure 28 can be increased by increasing a difference between the third refractive index and the fourth refractive index. On the contrary, the reflectivity of the second reflecting structure 28 can be decreased by decreasing a difference between the third refractive index and the fourth refractive index. In the embodiment, the difference between the third refractive index and the fourth refractive index is between 0.4 and 1. For example, the second reflecting structure 28 comprises the third layer 28a, such as Alₓ₂Ga₍₁₋ₓ₂₎As, 0≦x2≦0.8, and the fourth layer 28b, such as Al_{y2}Ga_{(1-y2)}As, 0.8≦y2≦1, wherein the third layer 28a and the fourth layer 28b are alternately stacked to form one or more pairs of the stack.

In a variant of the embodiment, as shown in FIG. 4, in responding to reflect the light with a wavelength λ, the thickness of each of the layers 28a, 28b of the second reflecting structure satisfies the formula d=(λ/(4n))/cos θ₂, wherein n is the refractive index of the material of the layer 28a or 28b, θ₂ is the incident angle at which the light from the semiconductor stack 12 being incident to the second reflecting structure 28. The second reflecting structure 28 has a maximum reflectivity for the wavelength λ at the incident angle θ₂.

In a variant of the embodiment, the material of the low refractive index layer of the second reflecting structure 28 comprises more than 80% mole percentage of aluminum (Al), such as Al_{y2}Ga_{(1-y2)}As, 0.8≦y2≦1. A wet oxidation process is applied to the second reflecting structure 28 to oxidize Al_{y2}Ga_{(1-y2)}As of the exposed outer sidewall to form an oxidized region 281 and a un-oxidized region 282 surrounded by the oxidized region 281, wherein the oxidized region 281 comprises aluminum oxide and the un-oxidized region 282 comprises Al_{y2}Ga_{(1-y2)}As, 0.8≦y2≦1. From a top view of the light-emitting device 3, the oxidized region 281 comprises a surface area which is approximately 30˜80% of a surface area of the light-emitting device 3 to provide better reflectivity for the light emitted from the active layer 122.

In a variant of the embodiment, the light emitted from the semiconductor stack 12 is incident to a surface of the oxidized region 281. Because of the difference between the refractive index n₂ of the oxidized region 281 and the refractive index n₁ of the adjacent layer, such as the third layer 28a of the second reflecting structure 28, the layer of the semiconductor stack 12 or the first reflecting structure 14, when the light incident to the second reflecting structure 28 at the second incident angle θ₂ and the second incident angle θ₂ is larger than the critical angle θ=sin⁻¹(n₂/n₁), the light from the semiconductor stack 12 is totally reflected on the surface of the oxidized region 281.

As shown in FIG. 3, in accordance with an embodiment of the present disclosure, the second electrode 29 of the light-emitting device 2 comprises a bonding electrode 291, a current blocking layer 292 formed between the semiconductor stack 12 and the bonding electrode 291, and a plurality of extension electrodes 293 formed on the semiconductor stack 12. A position of the current blocking layer 292 is approximately align to that of the un-oxidized region 282 shown in FIG. 4, and an outer periphery of the current blocking layer 292 is separated from an inner periphery of the oxidized region 281 with a distance from a top view of the light-emitting device 2. In order to spread the electrical current uniformly, the plurality of extension electrodes 293 is extended outwardly from the bonding electrode 291 on a surface of the semiconductor stack 12, and a position of the extension electrode 293 is approximately align to that of the oxidized region 281 shown in FIG. 4.

In an embodiment of the present disclosure, as shown in FIG. 1 and FIG. 2, a manufacturing method of a light-emitting device 1 or 2 comprises providing a substrate 10; providing a semiconductor stack 12 capable of emitting a light having a dominant wavelength; providing a reference wavelength; providing a first reflecting structure 14 between the substrate 10 and the semiconductor stack 12, wherein the first reflecting structure 14 has a first maximum reflectivity for the dominant wavelength normally incident to the first reflecting structure 14; and providing a second reflecting structure 16 between the substrate 10 and the semiconductor stack 12, wherein the second reflecting structure 16 has a second maximum reflectivity for the reference wavelength normally incident to the second reflecting structure 16 and for the dominant wavelength obliquely incident to the first reflecting structure 16. Here, the term “normally incident” means the light is incident on a layer at 0 degree, and the term “obliquely incident” means the light is incident on a layer at an angle off the normal of the layer.

Because the light emitted from the semiconductor stack 12 is toward multiple directions, a first part of the light is away from the substrate, and a second part of the light is toward the substrate. In order to reflect the second part of the light toward the light extraction surface to improve the light extraction efficiency of the light-emitting device 1 or 2, multiple reference wavelengths are needed when designing the multiple reflecting structures to have a maximum reflectivity at an incident angle of 0 degree. Thus, the multiple reflecting structures have a maximum reflectivity to the incident light having a dominant wavelength at different incident angles.

For example, the dominant wavelength of the light emitted from the active layer 122 is 650 nm. Here, the first reflecting structure 14 has a maximum reflectivity to the incident light having the dominant wavelength of 650 nm at an incident angle of 0 degree. A first part of the light from the active layer 122 is reflected back toward the semiconductor stack 12 by the first reflecting structure 14 when the first part of the light is normally incident to the first reflecting structure 14. A second part of the light not normally incident to the first reflecting structure 14 is obliquely incident to the first reflecting structure 14 at an incident angle far from the normal of the first reflecting structure 14, such as at 45°.

The second part of the light transmits through the first reflecting structure 14 and is obliquely incident on the second reflecting structure 16. Because the first reflecting structure 14 comprises a thickness, an optical path length of the second portion of the light transmitting through the first reflecting structure 14 is longer compared to that of the first part of the light normally incident to the first reflecting structure 14. As a result, a reference wavelength is provided for the second reflecting structure 16 to have a maximum reflectivity for the reference wavelength at an incident angle of 0°, wherein the reference wavelength is a virtual wavelength and is not an actual wavelength emitted from the active layer 122. In the present embodiment, the reference wavelength is longer than the dominant wavelength emitted from the active layer 122 and can be 700 nm, 760 nm, 810 nm, 860 nm, or 910 nm. Thus, the second reflecting structure 16 has a maximum reflectivity to the light having the dominant wavelength of 650 nm at an incident angle far from the normal of the second reflecting structure 16, such as at 45°.

Each reflecting structure, such as the first reflecting structure 14 or the second reflecting structure 16, is transparent to the light having the dominant wavelength emitted from the active layer 122 and comprises one or more DBR pairs of a high refractive index layer and a low refractive index layer. In accordance with formula d=(λ/(4n))/cos θ, wherein n is the refractive index of the high refractive index layer or the low refractive index layer, and θ is the incident angle that the light from the semiconductor stack 12 incident thereon. When a reference wavelength is provided to design the reflecting structure having a maximum reflectivity for the reference wavelength at incident angle of 0°, as the reference wavelength increases, the thickness of the high refractive index layer and the low refractive index layer is increased. A thickness of the low refractive index layer is thicker than that of the high refractive index layer.

In accordance with an embodiment of the present disclosure, the high refractive index layer in the DBR pair of the first reflecting structure 14 is abutting the semiconductor stack 12.

In accordance with an embodiment of the present disclosure, the low refractive index layer in the DBR pair of the second reflecting structure 16 is closer to the substrate 10 than the high refractive index layer in the DBR pair of the second reflecting structure 16 is to the substrate 10.

In accordance with an embodiment of the present disclosure, a refractive index of the high refractive index layer and the low refractive index layer of any reflecting structure 14, 16, or 18 is larger than that of the semiconductor stack 12 and lower than that of the substrate 10.

It will be apparent to those having ordinary skill in the art that various modifications and variations can be made in accordance with the present disclosure without departing from the scope or spirit of the disclosure. In view of the foregoing, it is intended that the present disclosure cover modifications and variations of this disclosure provided they fall within the scope of the following claims and their equivalents.

What is claimed is:

1. A light-emitting device, comprising:
a substrate;
a semiconductor stack capable of emitting a light;
a first reflecting structure between the substrate and the semiconductor stack to reflect the light; and
a second reflecting structure between the substrate and the semiconductor stack, wherein the first reflecting structure has a maximum reflectivity when the light is incident to the first reflecting structure at a first incident angle, the second reflecting structure has a maximum reflectivity when the light incident to the second reflecting structure at a second incident angle, and the second incident angle is larger than the first incident angle.

2. The light-emitting device of claim 1, wherein the second reflecting structure is between the substrate and the first reflecting structure, the material of the second reflecting structure comprises AlₓGa₍₁₋ₓ₎As, and 0.8≦x≦1.

3. The light-emitting device of claim 2, wherein the second reflecting structure comprises an un-oxidized region and an oxidized region surrounding the un-oxidized region; wherein the un-oxidized region comprises AlₓGa₍₁₋ₓ₎As and the oxidized region comprises aluminum oxide.

4. The light-emitting device of claim 3, wherein the oxidized region comprises a critical angle smaller than the second incident angle, and the first incident angle is smaller than the critical angle.

5. The light-emitting device of claim 3, further comprising a current blocking layer and an extension electrode on the semiconductor stack, wherein a position of the current blocking layer is approximately align to that of the un-oxidized region, a position of the extension electrode is approximately align to that of the oxidized region.

6. The light-emitting device of claim 5, wherein an outer periphery of the current blocking region is separated from an inner periphery of the oxidized region with a distance.

7. The light-emitting device of claim 1, wherein the first reflecting structure comprises a first stack comprising a pair provided with a first layer having a first refractive index and a second layer having a second refractive index, the second reflecting structure comprises a second stack comprising a pair provided with a third layer having a third refractive index and a fourth layer having a fourth refractive index, any layer of the first reflecting structure and the second reflecting structure comprises a thickness approximately multiple of one-quarter of the wavelength of the light.

8. The light-emitting device of claim 7, wherein the first reflecting structure comprises a first number of the pair of the first stack, the second reflecting structure comprises a second number of the pair of the second stack, the first number is different from the second number, or a first thickness of the pair of the first stack is different from a second thickness of the pair of the second stack.

9. The light-emitting device of claim 7, wherein a difference between the first refractive index and the second refractive index is between 0.4 and 1, a difference between the third refractive index and the fourth refractive index is between 0.4 and 1.

10. The light-emitting device of claim 7, further comprising a third reflecting structure between the first reflecting structure and the second reflecting structure, wherein the third reflecting structure has a maximum reflectivity when the light incident to the third reflecting structure at a third incident angle, the third incident angle is between the first incident angle and the second incident angle, the third reflecting structure comprises a third stack comprising a pair provided with a fifth layer comprising a fifth refractive index and a sixth layer comprising a sixth refractive index, a third thickness of the pair of the third stack is between the first thickness and the second thickness.

11. A light-emitting device, comprising:
a substrate;
a semiconductor stack capable of emitting a light having a dominant wavelength;
a first reflecting structure between the substrate and the semiconductor stack, wherein the first reflecting structure has a first maximum reflectivity to the dominant wavelength normally incident to the first reflecting structure; and
a second reflecting structure between the substrate and the semiconductor stack, wherein the second reflecting structure comprises a second maximum reflectivity to a reference wavelength incident normally to the second reflecting structure and to the dominant wavelength obliquely incident to the second reflecting structure.

12. The light-emitting device of claim 11, wherein each of the first reflecting structure and the second reflecting structure comprises one or more DBR pairs, each DBR pair is formed by a high refractive index layer and a low refractive index layer.

13. The light-emitting device of claim 12, wherein the high refractive index layer in the DBR pair of the first reflecting structure is abutting the semiconductor stack.

14. The light-emitting device of claim 12, wherein the low refractive index layer in the DBR pair of the second reflecting structure is closer to the substrate than the high refractive index layer in the DBR pair of the second reflecting structure is to the substrate.

15. The light-emitting device of claim 12, wherein a thickness of one pair of the high refractive index layer and the low refractive index layer of the second reflecting structure is larger than a thickness of one pair of the high refractive index layer and the low refractive index layer of the first reflecting structure.

16. The light-emitting device of claim 12, wherein a thickness of the low refractive index layer in the DBR pair is thicker than that of the high refractive index layer in the DBR pair.

17. The light-emitting device of claim 12, wherein a refractive index of the high refractive index layer and the low refractive index layer is larger than that of the semiconductor stack and lower than that of the substrate.

18. The light-emitting device of claim 11, wherein the reference wavelength is longer than the first dominant wavelength.

19. The light-emitting device of claim 11, wherein the second reflecting structure is transparent to the dominant wavelength.

20. The light-emitting device of claim 11, wherein the dominant wavelength is obliquely incident to the second reflecting structure at an angle larger than 0 degree and smaller than 90 degrees.
